(19) United States
(12) Patent Application Publication
(10) Pub. No.: US 2006/0190801 A1
(43) Pub. Date: Aug. 24, 2006

(54) Apparatus and method for generating low density parity check code using zigzag code in a communication system

(75) Inventors: Dong-Joon Shin, Seoul (KR); Song-Nam Hong, Seoul (KR)

Correspondence Address: DILWORTH & BARRESE, LLP, 333 EARLE OVINGTON BLVD., UNIONDALE, NY, 11553, US

(73) Assignees: SAMSUNG ELECTRONICS CO., LTD., Suwon-si (KR); SEOUL National University Industry Foundation, Seoul (KR)

(21) Appl. No.: 11/359,249

(22) Filed: Feb. 22, 2006

(30) Foreign Application Priority Data
Feb. 22, 2005 (KR) 2005-14732

(51) Int. Cl. H03M 13/00

(52) U.S. Cl. 714/758

(57) ABSTRACT

A method for generating a low-density parity check (LDPC) code supporting various code rates. The method includes finding a plurality of parity check matrixes showing the best performance at a predetermined code rate; matching the parity check matrixes in terms of the number of ‘1’s per row in units of sub-matrixes of each of the matrixes; and converting the plurality of parity check matrixes into one matrix, and combining punctured zigzag codes generated for every code rate into one punctured zigzag code.

### PRIORITY

This application claims the benefit under 35 U.S.C. § 119(a) of an application entitled “Apparatus and Method for Generating Low Density Parity Check Code Using Zigzag Code in a Communication System” filed in the Korean Intellectual Property Office on Feb. 22, 2005 and assigned Serial No. 2005-14732, the entire contents of which are incorporated herein by reference.

### BACKGROUND OF THE INVENTION

1. Field of the Invention

The present invention relates generally to a wireless communication system, and in particular, to an apparatus and method for generating a Low Density Parity Check (LDPC) code capable of supporting various code rates in a wireless communication system.

2. Description of the Related Art

The key issue in a communication system is how to efficiently and reliably transmit data over a channel. As the multimedia communication system, active research on which is now underway, requires a high-speed communication system capable of transmitting various information such as image and radio data as well as voice data, there is a need to increase system efficiency using a channel coding scheme appropriate for the system.

However, a wireless channel environment in the communication system, unlike the wire channel environment, suffers inevitable errors due to various factors such as multipath interference, shadowing, propagation attenuation, time-varying noise, and fading, causing information loss. The information loss leads to serious distortion in actual transmission signals, causing deterioration in the entire performance of the communication system. Generally, in order to reduce the information loss, various error control techniques are used according to channel characteristic to increase system reliability. A technique using an error correction code is one typical error control techniques.

The typical error correction codes include turbo codes and LDPC codes.

It is known that the LDPC code is superior to the convolutional code which is conventionally used for error correction in performance gain during high-speed data transmission. The LDPC code can effectively correct an error caused by noise generated in a wireless channel, thereby increasing data transmission reliability. In addition, the LDPC code can be decoded in a factor graph using a sum-product algorithm-based iterative decoding algorithm. Using a decoding method based on the sum-product algorithm-based iterative decoding algorithm, an LDPC decoder is lower in complexity than the turbo decoder and can be easily implemented with a parallel processing decoder.

The turbo code has superior performance approaching the channel capacity limit of Shannon's channel coding theorem, and the LDPC code having the best performance ever known, which uses a block size of 10⁷, shows performance having a difference of only about 0.04[dB] at the channel capacity limit of the Shannon's channel coding theorem at a bit error rate (BER) of 10⁻⁵. The Shannon's channel coding theorem shows that reliable communication is possible only for a data rate not exceeding the channel capacity. A random code with a very larger block size shows performance approaching the channel capacity limit in the Shannon's channel coding theorem. However, when maximum a posteriori (MAP) or maximum likelihood (ML) decoding is applied to the random code, the calculation is very complex, increasing a calculation load. The increase in the calculation load makes it impossible to implement the random code.

The LDPC code is defined by a parity check matrix in which a majority of elements have a value of 0 (Null) and a minority of elements, except for those elements having a value of 0, or having a value of 1. That is, the parity check matrix of the LDPC code has a very low weight. Therefore, the LDPC code can be decoded through iterative decoding even at a block code with a longer length, and if a length of the block code continues to increase, the LDPC code shows performance approaching the channel capacity limit of the Shannon's channel coding theorem, like the turbo code. Because of these advantages, the LDPC code tends to be used in the communication system as the error correction code.

However, when the LDPC code is encoded using a generator matrix, like the space-time code (STC), its superior performance cannot be guaranteed. That is, the LDPC code has low decoding complexity because its parity check matrix has a low weight as described above. However, if the parity check matrix is converted into a generator matrix, a weight of the generator matrix increases, causing an increase in the decoding complexity.

Therefore, active research has been conducted on new coding and decoding techniques for the communication system. A Concatenated Zigzag (CZZ) code proposed by Ping as a result of that search has advantages of both the turbo code and the LDPC code. The CZZ code compared with the turbo code, has lower decoding complexity because it is decoded by the sum-product algorithm. In addition, the CZZ code compared with the turbo code, shows an error floor at a low BER at a high code rate. Further, compared with the LDPC code, the CZZ code has low coding complexity.

However, the CZZ code is lower than the turbo code or the LDPC code in terms of its own error correction capability.

Below is a description of a rate-compatible channel code. Foremost is a description of the reason why the rate-compatible channel code is important.

First, the rate-compatible channel code has low coding and decoding complexity in algorithm and hardware implementation.

Second, the rate-compatible channel code can be readily used for Type-II Hybrid Automatic Repeat reQuest (HARQ) implementation. When an Incremental Redundancy (IR) scheme is used, a rate-compatible puncturing pattern is necessarily required.

Third, the rate-compatible channel code can be readily used for implementation of Adaptive Modulation and Coding (AMC) that changes a modulation scheme and a code rate according to channel condition.

Type-I HARQ uses a forward error correction (FEC) code as an error correction code for error detection in an error correction process, and makes a retransmission request using an Automatic Repeat reQuest (ARQ) technique. Type-I HARQ increases overhead for each transmission because it should detect another error pattern immediately after correcting an error pattern. Type-II HARQ has been proposed to make up for the defects of Type-I HARQ, and a concept of a variable redundancy code for Type-II HARQ was first introduced by Mandelbaum. Type-II HARQ based on the variable redundancy code has been proposed by Lin, Yu, Metzner, Wang and Lin.

Meanwhile, for error detection only a common message is encoded along with parity check bits. In this case, a receiver stores a received block in its buffer and detects an error therein, and sends a retransmission request upon detecting an error. Upon receiving the retransmission request, a transmitter transmits a block of parity check bits, and the receiver uses the transmitted block in correcting the error of the block stored in its buffer. If the error was successfully corrected, the receiver transmits the block to its user. However, if the error was not corrected, the receiver sends a retransmission request to the transmitter.

Assuming that an error correction code and a retransmission method are appropriately selected, Type-II provides higher performance compared with Type-I. If parity check bits corresponding to various puncturing patterns for compatibility are sequentially used for Type-II, throughput increases according to error correction capability corresponding to each data rate. Therefore, in increasing throughput of Type-II HARQ, it is most important to use a high-performance rate-compatible code.

AMC uses various combinations of modulation schemes and code rates according to channel conditions. The use of AMC can maximize average throughput at a desired frame error rate (FER). For example, a downlink of the 3^{rd} generation (3G) system provides a data rate of up to 5Mbps, and High Speed Downlink Packet Access (HSDPA) provides a full data rate of 10.8Mbps and uses AMC and HARQ as its core technologies.

However, because the communication system requires a data rate higher than that of HSDPA, the AMC technique for the next generation mobile communication should provide a greater number of combinations of modulation schemes and code rates, compared with the AMC technique used in the 3G system or HSDPA. A channel code used for the AMC technique needs various code rates, and in order to reduce hardware or algorithm complexity, it is preferable to provide various code rates by puncturing a mother code with a low code rate. The channel code should have excellent performance for various frame lengths.

A rate-compatible convolutional code is acquired by adding a rate compatible restriction to a puncturing method. The restriction needs the code rates provided in such a manner that all codes with a low code rate are used as all coded bits of a code with a high code rate using an appropriate puncturing pattern. Such a concept is extended to the turbo codes, and called “Rate Compatible Turbo Codes (RCTC).” The RCTC code has an error floor within a range of an appropriate signal-to-noise ratio (SNR) by low-weight codewords. In particular, for a high code rate and a short frame length, an influence of the error floor becomes serious and causes a serious problem in reliable data transmission.

As described above, the conventional technology, as it adjusts a code rate depending on only puncturing, excessively increases in the ratio of puncturing nodes, causing a dramatic reduction in performance and an increase in the error floor.

Therefore, there is a need for a rate-compatible channel code using an LDPC code.

### SUMMARY OF THE INVENTION

It is, therefore, an object of the present invention to provide a scheme for generating a rate-compatible LDPC code capable of supporting various code rates using symbol puncturing and pruning in a communication system.

It is another object of the present invention to provide a scheme for generating a rate-compatible LDPC code capable of showing the same performance as that of Irregular Concatenated Zigzag (ICZZ) codes designed for a particular code rate and preventing performance degradation due to the support of the rate compatibility.

It is further another object of the present invention to provide a rate-compatible LDPC code design scheme capable of determining a possible short period and allowing unpunctured parity bits to have a constant interval within the determined period.

It is yet another object of the present invention to provide a channel coding apparatus and method for increasing system efficiency by using the channel coding technique used in a communication system.

It is still another object of the present invention to provide a channel coding apparatus and method for maintaining the best performance for a code rate and reducing coding complexity and a decoding delay through performance improvement for a code used in a communication system.

It is still another object of the present invention to provide a channel coding apparatus and method for maintaining the best performance and a decoding delay regardless of code rates.

According to one aspect of the present invention, there is provided a method for generating a low-density parity check (LDPC) code supporting various code rates. The method includes finding a plurality of parity check matrixes showing the best performance at a predetermined code rate; matching the parity check matrixes in terms of the number of ‘1’s per row in units of sub-matrixes of each of the matrixes; converting the plurality of parity check matrixes into one matrix; and combining punctured zigzag codes generated for every code rate into one punctured zigzag code.

According to another aspect of the present invention, there is provided a method for generating a low-density parity check (LDPC) code supporting various code rates. The method includes determining the shortest period of a puncturing pattern; and determining positions of unpunctured parity bits such that the unpunctured parity bits have a constant interval within the determined period.

According to still another aspect of the present invention, there is provided an apparatus for generating a low-density parity check (LDPC) code supporting various code rates. The apparatus includes a zigzag encoder; a divider for dividing input information bits; a pruner for receiving the information bits divided by the divider, and pruning an input to the zigzag encoder, a puncturing pattern of the input being a zero (null) for the input information bits; and a puncturer for performing puncturing to match zigzag codes output from the zigzag encoder in terns of the number of ‘1’s per row.

### BRIEF DESCRIPTION OF THE DRAWINGS

The above and other objects, features and advantages of the present invention will become more apparent from the following detailed description when taken in conjunction with the accompanying drawings in which:

FIG. 1 is a diagram illustrating a general zigzag code;

FIG. 2 is a schematic diagram illustrating a structure of a general ICZZ encoder;

FIG. 3 is a schematic diagram illustrating a structure of a general serial decoder for an ICZZ code;

FIG. 4 is a schematic diagram illustrating a structure of a general hybrid decoder for an ICZZ code;

FIG. 5 is a diagram illustrating a Tanner graph for a general ICZZ code;

FIG. 6 is a schematic diagram illustrating an exemplary structure of an RC-LDPC encoder according to the present invention;

FIGS. 7A and 7B are diagrams illustrating Tanner graphs of general punctured zigzag codes;

FIGS. 8A and 8B are diagrams for a description of a puncturing pattern according to the present invention;

FIG. 9 is a schematic diagram illustrating a structure of an RC-LDPC encoder according to the present invention; and

FIG. 10 is a diagram for a description of an operation and structure of a puncturer according to the present invention.

### DETAILED DESCRIPTION OF EXEMPLARY EMBODIMENTS

Exemplary embodiments of the present invention will now be described in detail with reference to the annexed drawings. In the following description, a detailed description of known functions and configurations incorporated herein has been omitted for clarity and conciseness.

Before a detailed description of the present invention is given, a description will now be made of a zigzag code-based structured Low Density Parity Check (LDPC) code, i.e., an Irregular Concatenated Zigzag (ICZZ) code, according to the present invention.

One of the methods for reducing coding calculation of an LDPC code can express a part mapped to parity bits with a dual diagonal in a parity check matrix H. By expressing a part mapped to parity bits with a dual diagonal in a parity check matrix H, it is possible to express a parity generation block with an accumulator. A systematic data part irregularly defined in the parity check matrix H can be expressed as a combination of a repetition code and an interleaver. Generally, among LDPC codes, an LDPC code group for reducing coding calculation by applying a restriction to a structure of the parity check matrix H is called a structured LDPC code. Below is a description of the ICZZ code.

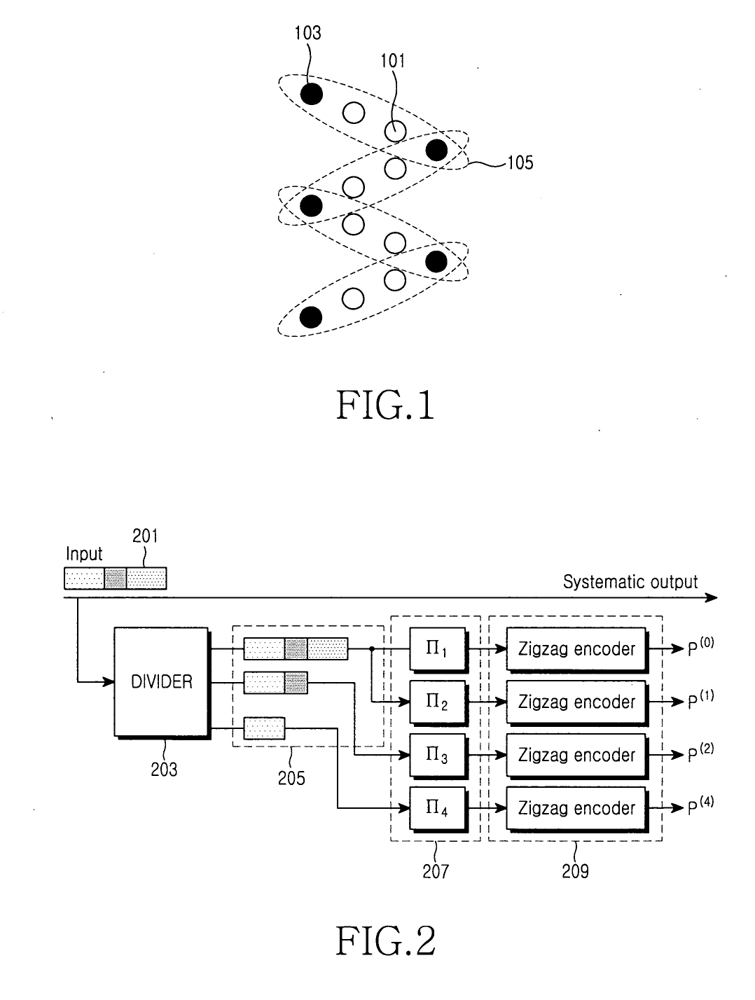

The ICZZ code, compared with the general LDPC code, can apply two-way scheduling. Therefore, it can show excellent performance even with a small number of iterations. In addition, the ICZZ code, which is an example of the structured LDPC code, has small coding calculation. The ICZZ code can be completely parameterized by \overline{R}=(R(1), R(2), . . . , R(Nₛ)) and \overline{d}_{c}=(d_{c}(1), d_{c}(2), . . . , d_{c}(Nₛ)), where R(i) and d_{c}(i) denote the fraction of information bits entering into the ith zigzag code and the check node degree for the ith zigzag code, respectively. The ICZZ code is specified by a ratio Ri of information bits input to a zigzag encoder and a parameter d_{c}(i)−2 used by the zigzag encoder. Herein, Rᵢ denotes a ratio of information bits input to an i^{th} zigzag encoder, and d_{c}(i)−2 denotes a parameter value of a zigzag code used by an i^{th} zigzag encoder. For example, if a first zigzag encoder uses a zigzag code shown in FIG. 1, d_{c}(1)=4. For example, d_{c}(i)−2 means that an i^{th} zigzag encoder uses a (d_{c}(i)−2)−zigzag code. With reference the accompanying drawings, below is a description of the zigzag code and the ICZZ code.

FIG. 1 is a diagram illustrating a general zigzag code, and FIG. 2 is a schematic diagram illustrating a structure of a general ICZZ encoder.

Referring to FIG. 1, therein is shown a zigzag code having a parameter value of 2. As illustrated in FIG. 1, white circles 101 represent information bits, black circles 103 represent parity bits, and dotted ellipses 105 are defined as segments. The parity bits are determined such that bits belonging to the segment satisfy an even parity as shown in FIG. 1.

In FIG. 1, the parameter having a value of 2 means that one parity bit is generated for every 2 information bits.

A structure of the ICZZ encoder is shown in FIG. 2. FIG. 2 shows an exemplary structure of an ICZZ encoder for Nₛ=4, where Nₛ denotes the number of zigzag codes.

Referring to FIG. 2, the ICZZ encoder includes an information bit block 201, a divider 203, a sub block 205, an interleaver 207, and a zigzag encoder 209. The interleaver 207 and the zigzag encoder 209 are generally constructed according to system setup. Herein, the number of both interleaver elements and zigzag encoder elements is equal to the number Nₛ=4 of the zigzag codes.

Below is a description of a coding process of the ICZZ encoder for Nₛ=4 illustrated in FIG. 2.
(1) The lengthen, information bit block 201 is input to the divider 203, and the divider 203 determines Nₛ sub blocks 205 input to their associated zigzag codes according to the number R(i) of information bits input to the zigzag encoder 209.
(2) Each of the Nₛ sub blocks 205 is input to its associated interleaver element 207. The Nₛ interleaver elements 207 are equal in size to their associated sub blocks 205.
(3) The sub blocks 205 interleaved by the interleaver elements 207 are input to their associated zigzag encoder elements 209. A coding process of the zigzag encoder 209 can be expressed in Equation (1) as follows:

$$P ( 1 ) = {\sum }_{j = 1}^{{d}_{c} ( i ) - 2} I ( j ) mod 2 \\ \begin{matrix}P ( i ) = {\sum }_{j = 1}^{{d}_{c} ( i ) - 2} I ( ( i - 1 ) + j + P ( j - 1 ) mod 2 , \\ i = 1 , 2 , 3 , ⋯ , {n}_{1} / ( {d}_{c} ( i ) - 2 )\end{matrix} \qquad ( 1 )$$

In Equation (1), I(j) denotes a jₜₕ information bit, n_{I} denotes the total number of information bits, and d_{c}(i) denotes a parameter value of a zigzag code used for an ith zigzag encoder.

Above is a description of the ICZZ encoder, whereas, below is a descriptionof an ICZZ decoder.

The ICZZ code, which is an example of an irregular LDPC code, can be decoded by a sum-product algorithm that is generally used for decoding an LDPC code. Each sub-matrix of the ICZZ code can be decoded by a serial decoder, as it has a cycle-less tree structure.

The serial decoder, compared with the sum-product algorithm-based decoder, can show the same performance with less calculation. However, the serial decoder has a longer decoding delay time compared with the sum-product algorithm. Therefore, it is preferable to adaptively select a decoding algorithm according to the requirements needed by the system depending on whether the short decoding delay time is important or the less calculation is important.

Below is a description of a decoding algorithm combined of the serial decoder, and the sum-product algorithm proposed by Ping.

First, the sum-product algorithm, i.e., the general parallel decoder, will bedescribed below.

Generally, the ICZZ code can be expressed with a Tanner graph including check nodes and variable nodes, so it can be decoded by the sum-product algorithm. That is, during one iteration, the variable node delivers a message to the check node, and the check node performs processing in check node using the message received from the variable node. Thereafter, the check node delivers a new message generated through the processing to the variable node. Then the variable node performs processing in variable node using the new message delivered from the check node, and delivers the resultant message back to the check node. This process is achieved only between directly connected nodes, and is simultaneously performed for every variable node. Therefore, the sum-product algorithm-based decoding is short in terms of the decoding time required for one iteration. However, the sum-product algorithm-based decoding is low in terms of the convergence speed because messages are updated only by the directly connected nodes.

The serial decoder will now be described below.

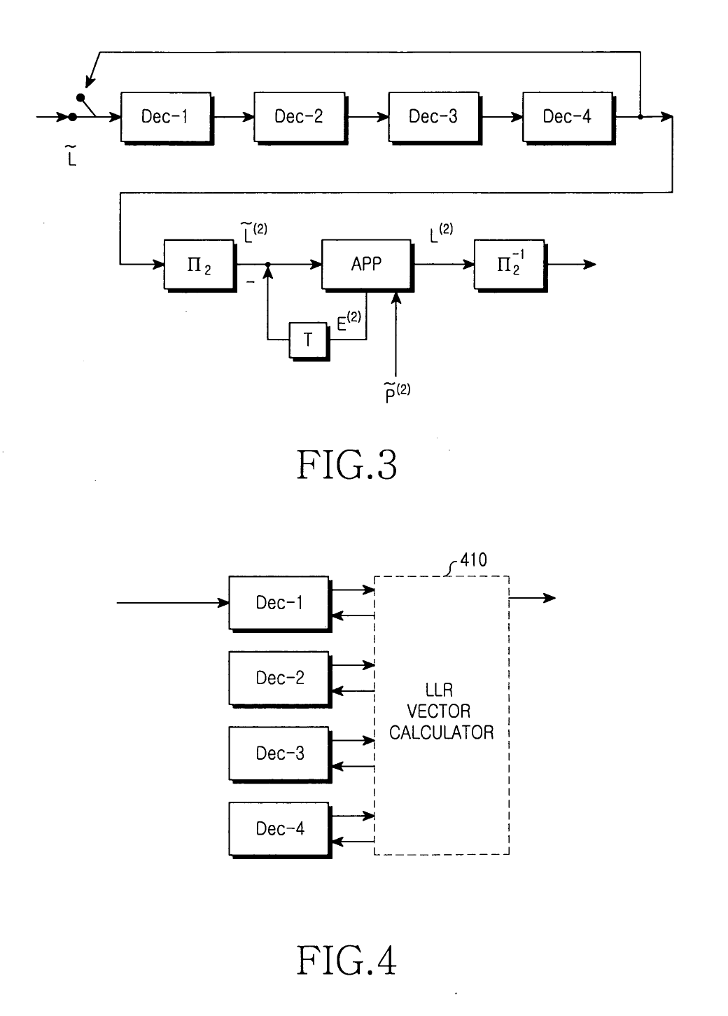

The serial decoder cannot be applied to the general LDPC code. It can only be applied to the LDPC code whose sub-matrix has a cycle-less tree structure, such as the ICZZ code. A structure of the serial decoder for the ICZZ code, matched to the ICZZ encoder of FIG. 2, is shown in FIG. 3.

FIG. 3 is a diagram schematic illustrating a structure of a general serial decoder for an ICZZ code.

Referring to FIG. 3, a parameter \tilde{L} represents an initial a priori Log-Likelihood Ratio (LLR) vector corresponding to information bits, a parameter \tilde{L}^{(m)} represents a priori LLR vector corresponding to information bits in an m^{th} decoder, a parameter L^{(m)} represents a posteriori LLR vector corresponding to information bits in an m^{th} decoder, a parameter \tilde{p}^{(m)} represents a priori LLR vector corresponding to parity bits in an m^{th} decoder, and a parameter E^{(m)} represents an extrinsic LLR vector delivered from an m^{th} decoder.

The extrinsic LLR vector E^{(m)} delivered from an m^{th} decoder, among the parameters, can be expressed in Equation (2) as follows:
E^{(m)}=L^{(m)}−(\tilde{L}^{(m)}−E_{last iteration}^{(m)} (2)

In Equation (2), E_{last iteration}^{(m)} denotes an extrinsic LLR vector calculated at the last iteration.

A decoding algorithm for the ICZZ code using the serial decoder can be expressed as Equation (3) and Equation (4) below.

Fist iteration:
\tilde{L}^{(m)}=\tilde{L}+E⁽¹⁾+E⁽²⁾+ . . . +E^{(m-1)} (3)

After first iteration:

$${\tilde{L}}^{( m )} = \tilde{L} + \begin{matrix}\underline{\underline{{E}^{( m )} + {E}^{( m + 1 )} + ⋯ + {E}^{( {N}_{s} )}}} \\ from the previous iteration\end{matrix} \\ \begin{matrix}\underline{\underline{+ {E}^{( 1 )} + {E}^{( 2 )} + ⋯ + {E}^{( m - 1 )}}} \\ from the current iteration\end{matrix} \qquad ( 4 )$$

In Equation (4), E^{(m)} is calculated at an m^{th} decoder Dec-m. Herein, because this value is not the value actually used in the m^{th} decoder, there is a part where the E^{(m)} is subtracted, as shown in FIG. 3.

A hybrid decoder will now be described below.

A calculation process performed in each sub-decoder of the hybrid decoder performs the same calculation process as that in the sub-decoder of the serial decoder. However, the hybrid decoder is implemented such that it can reduce a decoding delay time as compared with the serial decoder, by connecting its sub-decoders in parallel. As a result, the serial decoder increases in delay time in proportion to the number of sub-decoders, whereas the hybrid decoder is constant in the delay time regardless of the number of sub-decoders. Therefore, when many sub-decoders are required, the hybrid decoder is more efficient than the serial decoder. However, to show the same performance, the hybrid decoder needs more calculation as compared with the serial decoder. An exemplary structure of the hybrid decoder is shown in FIG. 4.

FIG. 4 is a schematic diagram illustrating a structure of a general hybrid decoder for an ICZZ code.

Referring to FIG. 4, the hybrid decoder includes a plurality of parallel-connected sub-decoders Dec-1 through Dec-4, and an LLR vector calculator 410. The LLR vector calculator 410 serves to calculate an extrinsic LLR vector.

The hybrid decoder is similar to the serial decoder in terms of the decoding algorithm used therefor. However, the hybrid decoder is different from the serial decoder in the process of calculating a posterior LLR vector, as set fourth in Equation (5):

$${\tilde{L}}^{( m )} = \tilde{L} + \begin{matrix}\underline{\underline{{E}^{( 1 )} + {E}^{( 2 )} + ⋯ + {E}^{( {N}_{s} )}}} \\ from the previous iteration\end{matrix} \qquad ( 5 )$$

As shown in Equation (5) above, the hybrid decoder simply uses the extrinsic LLR vector calculated at the previous iteration. Therefore, compared with the serial decoder that uses the extrinsic LLR vector at the current iteration, the hybrid decoder is low in the convergence speed. That is, the hybrid decoder needs more iterations.

Below is a description of a method for designing the ICZZ code described above.

The ICZZ code, which is a type of the structured LDPC code, can be expressed with a parity check matrix defined by Equation (6) as follows:

$$H = [ \begin{matrix}{S}_{1} \\ {S}_{2} \\ {S}_{3} \\ {S}_{4} \\ ⋮ \\ {S}_{{N}_{s}}\end{matrix} ] = [ \begin{matrix}{H}_{I , 1} & {H}_{p , 1} & 0 & 0 & 0 & 0 & 0 \\ {H}_{I , 2} & 0 & {H}_{p , 2} & 0 & 0 & 0 & 0 \\ {H}_{I , 3} & 0 & 0 & {H}_{p , 3} & 0 & 0 & 0 \\ {H}_{I , 4} & 0 & 0 & 0 & {H}_{p , 4} & 0 & 0 \\ ⋮ & & & ⋮ & & ⋰ & ⋮ \\ {H}_{I , {N}_{s}} & 0 & 0 & 0 & 0 & 0 & {H}_{p , {N}_{s}}\end{matrix} ] \qquad ( 6 )$$

As shown in Equation (6), the parity check matrix of the ICZZ code is divided into Nₛ sub-matrixes, and each sub-matrix is divided into an all-zero matrix and two non-zero matrixes H_{1,(i)} and HP_{P,(i)}. The ICZZ code, which is a systematic code, is divided into a part mapped to information bits and a part mapped to parity bits in its parity check matrix. That is, in Equation (6), the H_{1,(i)} represents the part mapped to selected information bits and the H_{p,(i)} represents the part mapped to parity bits.

The H_{P,(i)} representing the parity bits has a constant Accumulate Form, and can be expressed in Equation (7) as follows:

$${H}_{P . ( i )} = [ \begin{matrix}1 & 0 & 0 & … & 0 \\ 1 & 1 & 0 & … & 0 \\ 0 & 1 & 1 & … & 0 \\ ⋮ & ⋮ & ⋮ & ⋮ & ⋮ \\ 0 & 0 & 0 & 1 & 1\end{matrix} ] \qquad ( 7 )$$

Parameters R(i) and d_{c}(i) of the ICZZ code has the following functions in generating the parity check matrix.

R(i) represents a ratio of non-zero columns in an i^{th} sub-matrix. If R(i)<1, the non-zero columns are located in the right side of H_{l,(i)} representing the selected information bits. A position of ‘1’ in the non-zero columns is determined by an interleaver used in the decoder. In addition, d_{c}(i) represents the number of ‘1’s in each row, and is determined based on a parameter value of a zigzag code used in the decoder.

A size of the parity check matrix H of the ICZZ code is expressed as n_{p×(n}ₗ+nₚ), where np denotes the number of parity bits. Based on this, a size of the sub-matrixes H_{l,(i)} and H_{p,(i)} of the parity check matrix H, and a code rate R of the ICZZ code can be defined as Equation (8) and Equation (9), respectively.

$$\begin{matrix}{H}_{I , ( i )} \text{:} {n}_{I} R ( i ) / ( {d}_{c} ( i ) - 2 ) ⨯ {n}_{I } matrix \\ {H}_{P , ( i )} \text{:} {n}_{I} R ( i ) / ( {d}_{c} ( i ) - 2 ) ⨯ {n}_{I} R ( i ) / ( {d}_{c} ( i ) - 2 ) matrix & ( 8 ) \\ R = \frac{{n}_{I}}{{n}_{I} + {n}_{p}} = \frac{1}{1 + {\sum }_{i = 1}^{{N}_{c}} \frac{R ( i )}{{d}_{c} ( i ) - 2}} & ( 9 )\end{matrix}$$

It can be understood from Equation (9) that various ICZZ codes can be designed by changing R(i) and d_{c}(i), for a given code rate. It is very important to find a code with the best performance among the codes described above.

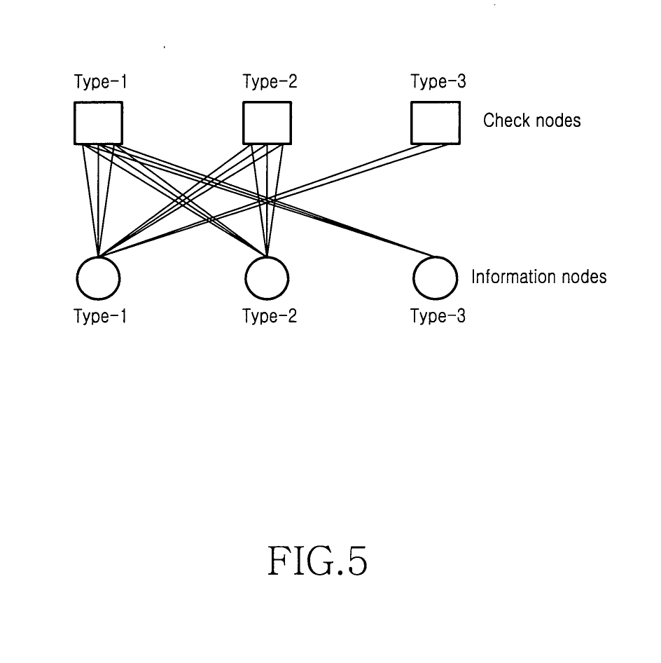

The process of designing the ICZZ code uses a density evolution technique generally applied to the LDPC code, and can form a Tanner graph shown in FIG. 5, using the parameters R(i) and d_{c}(i), for a general ICZZ code.

Referring to FIG. 5, the ICZZ code has check nodes and information nodes. That is, in FIG. 5, the ICZZ code has check nodes represented by squares and information nodes represented by circles, and the information nodes select variable nodes connected to the check nodes.

By using the density evolution based on Gaussian approximation, the recursion equations suitable to ICZZ codes are derived. The information nodes can be classified by the degrees of information nodes and the check nodes can be classified by the types of information nodes connected to the check nodes. Suppose that there are M different classes of information nodes and check nodes, F. Let \overline{λ}ᵢ=(λᵢ(1), λᵢ(2), . . . , λᵢ(m)) denote a multi-edge degree where λᵢ(k), 1<i<M represents the number of edges between type-i information node and type-k check node.

To apply density evolution with Gaussian approximation to ICZZ codes, the degree and fraction of type-i information nodes shall be calculated from the given parameters R(i)'s. Partition R(i)'s into M sets Qⱼ, 1≦j≦M, such that R(i) and R(k) belong to the same set if and only if R(i)=R(j). Note that all elements of Qⱼ are identical and denote the representative element of Qⱼ by e(Qⱼ). Then, without loss of generality, we can assume that e(Qⱼ)<e(Qⱼ₊₁). Let |Qⱼ| be the number of elements in Qⱼ, then, the multi-edge degree of type-i information node becomes as expressed in Equation (10):
λᵢ(j)=|Qⱼ| if j≦M−(i−1), and λᵢ(j)=0 if j>M−(i−1) (10)

Then, the degree of type-i information nodes is

$${\sum }_{j = 1}^{m} {λ}_{i} ( j ) .$$

Let ƒₖ^{(j)} be the fraction of type-k information nodes among information nodes connected to the type-j check nodes. Then, it can be computed by Equation (11) as follows:

$${f}_{k}^{( j )} - {f}_{k} / {\sum }_{i = 1}^{M - ( j - 1 )} {f}_{i} , k = 1 , 2 , ⋯ , M - ( j - 1 ) \qquad ( 11 )$$

where ƒₖ denotes the fraction of type-k information nodes given by Equation (12):
ƒₖ=e(Q_{M-(k-1)})−e(Q_{M-(k-2)}) for 2≦k≦M, and ƒ₁=e(Q_{M}) (12)
Given the parameter \overline{R}=((1, 1, 1), (0.75, 0.75), (0.33, 0.33, 0.33)), we can derive the degree and fraction of type-i information nodes. By Equations (10) and (12), \overline{λ}₁=(3, 2, 3), \overline{λ}₂=(3, 2, 0), and \overline{λ}₃=(3, 0, 0), ƒ₁=0.33, ƒ₂=(0.75−0.33)=0.42, and ƒ₃=(1−0.75)=0.25.

At the lₜₕ iteration, Cⱼ^{(l)} and Pⱼ^{(l)} be the means of messages passed from type-j check nodes to information nodes and parity nodes, respectively, and V_{k,j}^{(l)} be the mean of message from type-k information node to type-i check node. Then, we get

$${V}_{k , j}^{( l )} = {m}_{0} + {\sum }_{t = 1 , t \neq j}^{M} {λ}_{k} ( t ) {C}_{t}^{( l - 1 )} + ( {λ}_{k} ( j ) - 1 ) {C}_{j}^{( l - 1 )} , k \leq M - ( j - 1 ) ,$$

where m₀ is the mean of initial LLR message received from the channel at a variable node. Finally, the recursion equations are obtained by DE with Gaussian approximation as follows in Equation (13) and (14):

$$\begin{matrix}{C}_{j}^{( l )} = {ϕ}^{- 1} ( 1 - {{[ 1 - {\sum }_{k = 1}^{M - ( j - 1 )} {f}_{k}^{( j )} ϕ ( {V}_{k , j}^{( l )} ) ]}^{{d}_{c} ( j ) - 3} [ 1 - ϕ ( {m}_{0} + {P}_{j}^{( l - 1 )} ) ]}^{2} ) , j = 1 , 2 , ⋯ , M & ( 13 ) \\ {P}_{j}^{( l )} = {ϕ}^{- 1} ( 1 - {[ 1 - {\sum }_{k = 1}^{M - ( j - 1 )} {f}_{k}^{( j )} ϕ ( {V}_{k , j}^{( l )} ) ]}^{{d}_{c} ( j ) - 2} [ 1 - ϕ ( {m}_{0} + {P}_{j}^{( l - 1 )} ) ] ) , j = 1 , 2 , ⋯ , M \\ where ϕ ( x ) ≡ 1 - 1 \sqrt{4 π x} {\int }_{R} tan h \frac{u}{2} {ⅇ}^{- {( u - x )}^{2} / 4 x} ⅆ u for x > 0 and ϕ ( x ) ≡ 1 for x = 0. & ( 14 )\end{matrix}$$

Since assume that all-0 codeword is transmitted, the iteration is started by the initial value m₀=2/σ² from the channel, where σ² is the noise variance. The number of iterations is sufficiently large enough to determine whether the error can be corrected for the given channel noise level and the threshold σ^{*} is obtained, which is defined as follows.

$$If σ < {σ}^{*} , {lim}_{l -> ∞} {P}_{e}^{( l )} = 0 , and If σ < {σ}^{*} , {lim}_{l -> ∞} {P}_{e}^{( l )} > 0 ,$$

where σ is the standard deviation of the AWGN channel and Pₑ^{(l)} is the error probability after lth iteration.

In a first embodiment, if it is assumed that for the set Qⱼ, Q₁={1, 1, 1}, Q₂={0.5515, 0.5515} and Q₃={0.299, 0.299, 0.299}, a desired parameter R(i) can be defined as Equation (15) as follows:
R(1)=R(2)=R(3)=e(Q₁)=1
R(4)=R(5)=e(Q₂)=0.5515 (15)
R(6)=R(7)=R(8)=e(Q₃)=0.299

In a second embodiment, for an ICZZ code with a code rate ½, the following is given.

Parameters of the ICZZ code showing the best performance at a code rate ½ found in the foregoing method can be represented by Table 1 below.

TABLE 1

| | | | | |
|---|---|---|---|---|
| \overline{λ}₁(1) | 3 | f₁⁽¹⁾ | 0.299 | d_{c}(j) = 7, |
| \overline{λ}₁(2) | 2 | f₁⁽²⁾ | 0.2525 | j = 1, 2, 3 |
| \overline{λ}₁(3) | 3 | f₁⁽³⁾ | 0.4485 | |

Threshold (σ*) = 0.935

The parameters used in the decoder can be found by substituting the parameters shown in Table 1 into Equation (10) through Equation (11). The parameters used in the decoder can be represented by Table 2 below.

TABLE 2

| | | |
|---|---|---|
| R(1) | 1 | d_{c}(j) = 7, |
| R(2) | | j = 1, 2, 3 |
| R(3) | | |
| R(4) | 0.5515 | |
| R(5) | | |
| R(6) | 0.299 | |
| R(7) | | |
| R(8) | | |

A definition of the ICZZ code according to an embodiment of the present invention has been described so far. The following is a description of a rate-compatible LDPC (RC-LDPC) code.

The RC-LDPC code according to the present invention means a code that can support various code rates using one encoder. That is, unpunctured parity bits used in a decoding process at a low supported code rate should include unpunctured parity bits used at a higher supported code rate. This characteristic means that the RC-LDPC code is appropriate for an IR-based Type-II HARQ system.

A description will now be made of a method for designing an RC-LDPC code according to the present invention, which can support various code rates using symbol puncturing or pruning. The proposed RC-LDPC code has almost no performance degradation due to the support of the rate compatibility because it shows almost same performance as that of the ICZZ code designed to be suitable for a particular code rate.

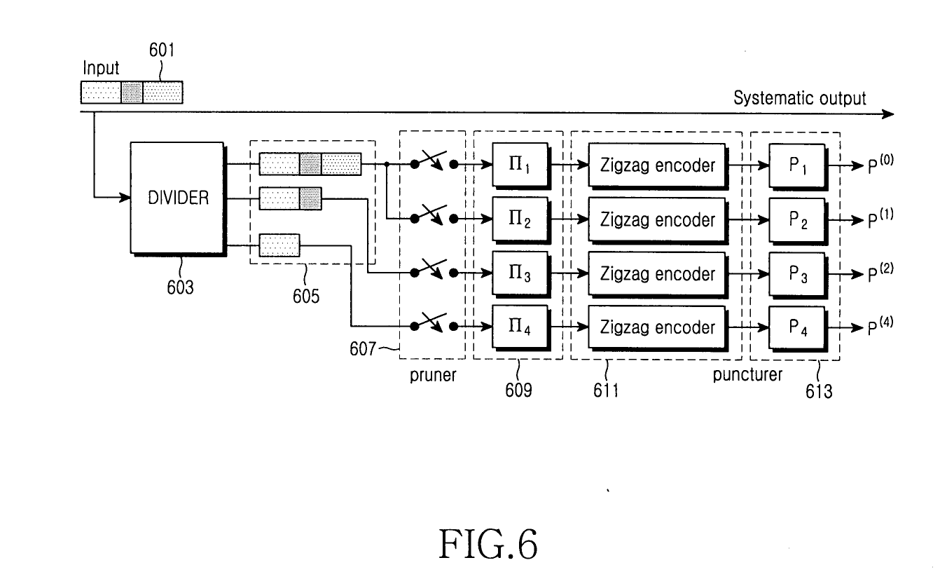

FIG. 6 is a schematic diagram illustrating an exemplary structure of an RC-LDPC encoder according to the present invention.

Referring to FIG. 6, therein is shown an RC-LDPC encoder according to the present invention. Specifically, FIG. 6 shows an exemplary structure of an RC-LDPC encoder including a puncturer for puncturing output values of each zigzag encoder. The RC-LDPC encoder includes an information bit block 601, a divider 603, a sub block 605, a pruner 607, an interleaver 609, a zigzag encoder 611, and a puncturer 613.

As illustrated in FIG. 6, the puncturer elements 613 are separately designed in association with their corresponding zigzag encoder elements 611. That is, the puncturers P₁, P₂, P₃ and P₄ are designed in association with their corresponding zigzag encoder elements 611 on a one-to-one basis.

A description will now be made of a process of designing an RC-LDPC code that supports N_{R} code rates

$${r}_{i} = \frac{{k}_{i}}{{n}_{i}} ,$$

1≦i≦N_{R}(kᵢ<kⱼ, i>j). The process is roughly divided into three sub-processes as set forth below.
(1) A parity check matrix Hᵢ (where 1≦i≦N_{R}) that shows excellent performance for each of the N_{R} code rates, which is found using the method descried for the ICZZ code, can be defined in Equation (16) as follows:

$${H}_{n} = [ \begin{matrix}{S}_{1}^{n} \\ {S}_{2}^{n} \\ {S}_{3}^{n} \\ {S}_{4}^{n} \\ ⋮ \\ {S}_{{N}_{j}}^{n}\end{matrix} ] = [ \begin{matrix}{H}_{1 , 1}^{n} & {H}_{p , 1}^{n} & 0 & 0 & 0 & 0 & 0 \\ {H}_{1 , 2}^{n} & 0 & {H}_{p , 2}^{n} & 0 & 0 & 0 & 0 \\ {H}_{1 , 3}^{n} & 0 & 0 & {H}_{p , 3}^{n} & 0 & 0 & 0 \\ {H}_{1 , 4}^{n} & 0 & 0 & 0 & {H}_{p , 4}^{n} & 0 & 0 \\ ⋮ & & & ⋮ & & ⋰ & ⋮ \\ {H}_{1 , {N}_{j}}^{n} & 0 & 0 & 0 & 0 & 0 & {H}_{p , {N}_{j}}^{n}\end{matrix} ] \qquad ( 16 )$$

A process of finding the parameters according to the present invention satisfies a condition of Equation (17) below.
R^{k}(i)≧R^{j}(i), k>j (17)

In Equation (18), R^{k}(i) denotes a ratio of non-zero columns of the H_{l,i}ⁿ in the parity check matrix Hᵢ shown in Equation (17), and R^{j}(i) denotes an i^{th} sub-matrix of a parity check matrix matched to a code rate specified in a system setup process. Herein, k, j and i represent random variables.
(2) In accordance with the general puncturing bit theorem, Sᵢ¹, Sᵢ², . . . , Sᵢ^{N}^{_{R}}(1≦i≦N_{R}) are matched in the number of ‘1’s per row. This process replaces a zigzag code with a punctured zigzag code with another possible check node degree. The puncturing bit theorem will be described later.
(3) To generate a matrix H, a puncturing pattern corresponding to the zigzag code created in sub-process (2) should be modified such that it satisfies a rate compatibility restriction.

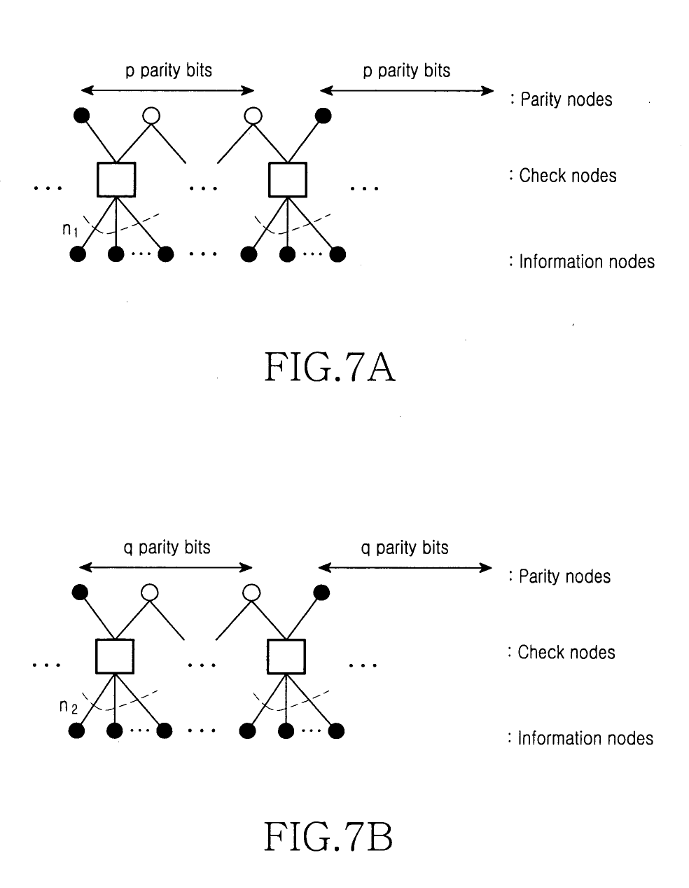

In sub-process (1), Hₙs(1≦i≦N_{R}) can be designed as shown in FIGS. 7A and 7B, and a description of sub-process (2) and (3) will be given in the next sections A and B. In the following description, a notation ‘(p)’ will be used for a puncturing pattern used for puncturing the last bit #(p−1) of every p parity bits from a zigzag encoder as shown in FIGS. 7A and 7B.
A. A detailed description of sub-process (2) will now be made. To create a parity check matrix H of an Hₙs-based RC-LDPC code, the number of ‘1’s in each row of Sᵢ¹, Sᵢ², . . . , Sᵢ^{N}^{_{R}} should be constant as assumed in sub-process (2). An i^{th} sub-matrix Sᵢ of the parity check matrix H is created using Sᵢ¹, Sᵢ², . . . , Sᵢ^{N}^{_{R}}. Herein, Sᵢⁿ refers to a (d_{c}ⁿ(i)−2)−zigzag code. If R^{k}(i)=0, Sᵢ^{k} does not greatly affect the creation of Sᵢ. According to the puncturing bit theorem, each zigzag code can be replaced with a zigzag code that was appropriately punctured without performance degradation. In other words, it is possible to match Sᵢ¹, Sᵢ², . . . , Sᵢ^{N}^{_{R}} in the number of ‘1’s in each row in the following procedure.
1) d_{c}(i) denotes the number of ‘1’s in a row of an i^{th} sub-matrix of the parity check matrix H, and is calculated by the following equation of d_{c}(i)=gcd(d_{c}¹(i)−2, d_{c}²(i)−2, . . . , d_{c}^{N}^{ᵢ}(i)−2)+2 , where gcd denotes the greatest common divisor. If d_{c}ⁿ(i)−2(1≦n≦N_{R}) is not defined for a certain n, the gcd operation is excluded. The foregoing equation represents the maximum value that can be satisfied to match the number of ‘1’s per row, and has the maximum value to reduce the number of punctured bits.
2) According to the puncturing bit theorem, a (dₙ(i)−2)−zigzag code can be replaced with a (d_{c}ⁿ(i)−2)−zigzag code that was punctured according to a puncturing pattern

$${P}_{i}^{k} = ( \frac{{ⅆ}_{c}^{k} ( i ) - 2}{{ⅆ}_{c} ( i ) - 2} ) .$$

Because the error floor becomes significant as the number of puncturing nodes increases, d_{c}(i) is selected in Procedure 1) such that it minimizes the number of puncturing nodes, while a rate compatibility condition is satisfied.
B. Because the number of ‘1’s in each row becomes constant by performing Procedure 1, the parity check matrix H can be created by including the following rate compatibility condition in the puncturing pattern.

Condition: a period of Pᵢ^{k} is a factor of a period Pᵢ^{j}(1≦j≦k −1).

If the condition is satisfied at 2≦k≦N_{R}, a puncturing pattern for the rate compatibility can be obtained without performance degradation.

With reference to FIGS. 7A and 7B, below is a description of the puncturing bit theorem.

FIGS. 7A and 7B are diagrams illustrating Tanner graphs of general punctured zigzag codes. Specifically, FIG. 7A illustrates a Tanner graph of a zigzag code with a puncturing pattern (p), and FIG. 7B illustrates a Tanner graph of a zigzag code with a puncturing pattern (q).

In FIGS. 7A and 7B, if n₁·p=n₂·q, an (n₁, 0)−zigzag code punctured in the puncturing pattern (p) can be replaced by an (n₂, 0)−zigzag code punctured in the puncturing pattern (q) that maintains the same error correction performance. Such a theorem is proven as follows.

The theorem can be proven by assuming the codes of FIGS. 7A and 7B as constituent codes of a CZZ code and connecting a code #1, i.e., a zigzag code with the puncturing pattern (p), and a code #2, i.e., a zigzag code with the puncturing pattern (q), to the same interleaver.

Referring to FIGS. 7A and 7B, shown are Tanner graphs of punctured zigzag codes, wherein black circles represent unpunctured bits and white circles represent punctured bits.

If averages of messages transmitted from check nodes to information nodes are equal in the density evolution analysis, two zigzag codes show the same error correction performance when they are used as constituent codes of the CZZ codes. Therefore, there is a need to show that mᵤ_{₁}_{^{(l)}}ⱼ and mᵤ_{₂}_{^{(l)}}₍ⱼ₎ are equal to each other. In FIGS. 7A and 7B, mᵤ_{₁}_{^{(l)}}₍ⱼ₎ and mᵤ_{₂}_{^{(l)}}₍ⱼ₎ represent averages of messages transmitted from a check node to a j^{th} information node at a I^{th} iteration for the code #1 and the code #2, respectively.

In the following description, N denotes the total number of information nodes. In FIGS. 7A and 7B, when puncturing periods p and q are taken into consideration, the N information nodes are divided into N/pn₁ and N/pn₂ groups, and a size of the group for the code #1 becomes nip while a size of the group for the code #2 becomes n₂q. As described above, the group size n₁p for the code #1 and the group size n₂q for the code #2 are equal to each other (n₁p=n₂q). In this case, an index j of the information node can be expressed as j=α·pn₁+k or j=α·qn₂+k(0≦α≦N/pn₁, 0≦k≦n₁p). This means that a jₜₕ information node can be applied to a k^{th} node in an α^{th} group in both the code #1 and the code #2.

It will be assumed herein that m_{L} and M_{R} denote averages of messages transmitted from left and right parity nodes to check nodes connected to a j^{th} information node, and mᵥ_{^{(l)}}₍ⱼ₎ denotes an average of messages transmitted from a j^{th} check node to an information node at a j^{th} iteration.

First, m_{L}, m^{R} and mᵤ_{₁}_{^{(l)}}₍ⱼ₎ for the code #1 induced in FIG. 7A can be expressed as Equation (18), Equation (19) and Equation (20), respectively.

$$\begin{matrix}\begin{matrix}{m}_{L} = {ϕ}^{- 1} ( 1 - {[ 1 - ϕ ( {m}_{{v}^{( l - 1 )}} ) ]}^{{n}_{1} \cdot ( k / {n}_{1} - 1 )} \cdot \\ [ 1 - ϕ ( {m}_{{u}_{0}} + {ϕ}^{- 1} ( 1 - {[ 1 - ϕ ( {m}_{{v}^{( l - 1 )}} ) ]}^{{n}_{1} \cdot p - 1} \cdot \\ [ 1 - ϕ ( {m}_{{u}_{0}} + {ϕ}^{- 1} ( 1 - {[ 1 - ϕ ( {m}_{{v}^{( l - 1 )}} ) ]}^{{n}_{1} \cdot p - 1} ⋯ \cdot \\ [ 1 - ϕ ( {m}_{{u}_{0}} + {ϕ}^{- 1} ( 1 - {[ 1 - ϕ ( {m}_{{v}^{( l - 1 )}} ) ]}^{{n}_{1} \cdot p - 1} ] \cdot \\ [ 1 - ϕ ( {m}_{{u}_{0}} ) ] ) ⋯ ) ] ) a - 1 terms \end{matrix} & ( 18 ) \\ \begin{matrix}{m}_{R} = {ϕ}^{- 1} ( 1 - {[ 1 - ϕ ( {m}_{{v}^{( l - 1 )}} ) ]}^{{n}_{1} ( p - k / {n}_{1} )} \cdot \\ [ 1 - ϕ ( {m}_{{u}_{0}} + {ϕ}^{- 1} ( 1 - {[ 1 - ϕ ( {m}_{{v}^{( l - 1 )}} ) ]}^{{n}_{1} \cdot p - 1} \cdot \\ [ 1 - ϕ ( {m}_{{u}_{0}} + {ϕ}^{- 1} ( 1 - {[ 1 - ϕ ( {m}_{{v}^{( l - 1 )}} ) ]}^{{n}_{1} \cdot p - 1} ⋯ \cdot \\ [ 1 - ϕ ( {m}_{{u}_{0}} + {ϕ}^{- 1} ( 1 - {[ 1 - ϕ ( {m}_{{v}^{( l - 1 )}} ) ]}^{{n}_{1} \cdot p - 1} ] \cdot \\ [ 1 - ϕ ( {m}_{{u}_{0}} ) ] ) ⋯ ) ] ) ( N / {pn}_{1} - a ) terms \end{matrix} & ( 19 ) \\ \begin{matrix}{m}_{{u}_{1}^{( l )} ( j )} = {ϕ}^{- 1} ( 1 - {[ 1 - ϕ ( {m}_{{v}^{( l - 1 )}} ) ]}^{{n}_{1} - 1} \cdot \\ [ 1 - ϕ ( {m}_{L} ) ] \cdot [ 1 - ϕ ( {m}_{R} ) ] ) \\ = {ϕ}^{- 1} ( 1 - {[ 1 - ϕ ( {m}_{{v}^{( l - 1 )}} ) ]}^{{n}_{1} \cdot p - 1} \cdot \\ [ 1 - ϕ ( {m}_{{u}_{0}} + {ϕ}^{- 1} ( 1 - {[ 1 - ϕ ( {m}_{{v}^{( l - 1 )}} ) ]}^{{n}_{1} \cdot p - 1} \cdot \\ [ 1 - ϕ ( {m}_{{u}_{0}} + {ϕ}^{- 1} ( 1 - {[ 1 - ϕ ( {m}_{{v}^{( l - 1 )}} ) ]}^{{n}_{1} \cdot p - 1} ⋯ \\ [ 1 - ϕ ( {m}_{{u}_{0}} + {{ϕ}^{- 1} ( 1 - ϕ ( {m}_{{v}^{( l - 1 )}} ) ]}^{{n}_{1} \cdot p - 1} \cdot \\ [ 1 - ϕ ( {m}_{{u}_{0}} ) ] ) ⋯ ) ] \cdot \\ [ 1 - ϕ ( {m}_{{u}_{0}} + {ϕ}^{- 1} ( 1 - {[ 1 - ϕ ( {m}_{{v}^{( l - 1 )}} ) ]}^{{n}_{1} \cdot p - 1} \cdot \\ [ 1 - ϕ ( {m}_{{u}_{0}} + {ϕ}^{- 1} ( 1 - {[ 1 - ϕ ( {m}_{{v}^{( l - 1 )}} ) ]}^{{n}_{1} \cdot p - 1} ⋯ \\ [ 1 - ϕ ( {m}_{{u}_{0}} + {{ϕ}^{- 1} ( 1 - ϕ ( {m}_{{v}^{( l - 1 )}} ) ]}^{{n}_{1} \cdot p - 1} \cdot \\ [ 1 - ϕ ( {m}_{{u}_{0}} ) ] ) ⋯ ) ] )\end{matrix} & ( 20 )\end{matrix}$$

Next, m_{L}, m_{R} and mᵤ_{₂}_{^{(l)}}₍ⱼ₎ for the code #2 induced in FIG. 7B can be defined as Equation (21), Equation (22) and Equation (23), respectively.

$$\begin{matrix}\begin{matrix}{m}_{L} = {ϕ}^{- 1} ( 1 - {[ 1 - ϕ ( {m}_{{v}^{( l - 1 )}} ) ]}^{{n}_{2} \cdot ( k / {n}_{2} - 1 )} \cdot \\ [ 1 - ϕ ( {m}_{{u}_{0}} + {ϕ}^{- 1} ( 1 - {[ 1 - ϕ ( {m}_{{v}^{( l - 1 )}} ) ]}^{{n}_{2} \cdot q - 1} \cdot \\ [ 1 - ϕ ( {m}_{{u}_{0}} + {ϕ}^{- 1} ( 1 - {[ 1 - ϕ ( {m}_{{v}^{( l - 1 )}} ) ]}^{{n}_{2} \cdot q - 1} ⋯ \cdot \\ [ 1 - ϕ ( {m}_{{u}_{0}} + {ϕ}^{- 1} ( 1 - {[ 1 - ϕ ( {m}_{{v}^{( l - 1 )}} ) ]}^{{n}_{2} \cdot q - 1} ] \cdot \\ [ 1 - ϕ ( {m}_{{u}_{0}} ) ] ) ⋯ ) ] ) a - 1 terms \end{matrix} & ( 21 ) \\ \begin{matrix}{m}_{R} = {ϕ}^{- 1} ( 1 - {[ 1 - ϕ ( {m}_{{v}^{( l - 1 )}} ) ]}^{{n}_{2} ( q - k / {n}_{2} )} \cdot \\ [ 1 - ϕ ( {m}_{{u}_{0}} + {ϕ}^{- 1} ( 1 - {[ 1 - ϕ ( {m}_{{v}^{( l - 1 )}} ) ]}^{{n}_{2} \cdot q - 1} \cdot \\ [ 1 - ϕ ( {m}_{{u}_{0}} + {ϕ}^{- 1} ( 1 - {[ 1 - ϕ ( {m}_{{v}^{( l - 1 )}} ) ]}^{{n}_{2} \cdot q - 1} ⋯ \cdot \\ [ 1 - ϕ ( {m}_{{u}_{0}} + {ϕ}^{- 1} ( 1 - {[ 1 - ϕ ( {m}_{{v}^{( l - 1 )}} ) ]}^{{n}_{2} \cdot q - 1} ] \cdot \\ [ 1 - ϕ ( {m}_{{u}_{0}} ) ] ) ⋯ ) ] ) ( N / {qn}_{2} - a ) terms \end{matrix} & ( 22 ) \\ \begin{matrix}{m}_{{u}_{2}^{( l )} ( j )} = {ϕ}^{- 1} ( 1 - {[ 1 - ϕ ( {m}_{{v}^{( l - 1 )}} ) ]}^{{n}_{2} - 1} \cdot \\ [ 1 - ϕ ( {m}_{L} ) ] \cdot [ 1 - ϕ ( {m}_{R} ) ] ) \\ = {ϕ}^{- 1} ( 1 - {[ 1 - ϕ ( {m}_{{v}^{( l - 1 )}} ) ]}^{{n}_{2} \cdot q - 1} \cdot \\ [ 1 - ϕ ( {m}_{{u}_{0}} + {ϕ}^{- 1} ( 1 - {[ 1 - ϕ ( {m}_{{v}^{( l - 1 )}} ) ]}^{{n}_{2} \cdot q - 1} \cdot \\ [ 1 - ϕ ( {m}_{{u}_{0}} + {ϕ}^{- 1} ( 1 - {[ 1 - ϕ ( {m}_{{v}^{( l - 1 )}} ) ]}^{{n}_{2} \cdot q - 1} ⋯ \\ [ 1 - ϕ ( {m}_{{u}_{0}} + {{ϕ}^{- 1} ( 1 - ϕ ( {m}_{{v}^{( l - 1 )}} ) ]}^{{n}_{2} \cdot q - 1} \cdot \\ [ 1 - ϕ ( {m}_{{u}_{0}} ) ] ) ⋯ ) ] \cdot \\ [ 1 - ϕ ( {m}_{{u}_{0}} + {ϕ}^{- 1} ( 1 - {[ 1 - ϕ ( {m}_{{v}^{( l - 1 )}} ) ]}^{{n}_{2} \cdot q - 1} \cdot \\ [ 1 - ϕ ( {m}_{{u}_{0}} + {ϕ}^{- 1} ( 1 - {[ 1 - ϕ ( {m}_{{v}^{( l - 1 )}} ) ]}^{{n}_{2} \cdot q - 1} ⋯ \\ [ 1 - ϕ ( {m}_{{u}_{0}} + {{ϕ}^{- 1} ( 1 - ϕ ( {m}_{{v}^{( l - 1 )}} ) ]}^{{n}_{2} \cdot q - 1} \cdot \\ [ 1 - ϕ ( {m}_{{u}_{0}} ) ] ) ⋯ ) ] )\end{matrix} & ( 23 )\end{matrix}$$

It can be noted from Equation (18) through Equation (23) that mᵤ_{₁}_{^{(l)}}₍ⱼ₎ and mᵤ_{₂}_{^{(l)}}₍ⱼ₎ are equal to each other by n₁·p=n₂·q.

A description will now be made of sub-process (3), i.e., a process of applying the rate compatibility for the puncturing patterns generated in the foregoing process.

First, because the Sᵢ^{k}, (1≦k≦N_{R}) are matched in the number of ‘1’s per row in the above process, a sub-matrix Sᵢ of the parity check matrix H of the RC-LDPC code can be created by simply allowing the induced puncturing patterns to satisfy the rate compatibility. Assume that a parity bit stream generated at an i^{th} zigzag encoder for the designed RC-LDPC code is denoted by Pa(j)(1≦j≦Nₚ).

In this case, if the rate compatibility is not taken into consideration, unpunctured parity bits corresponding to the Sᵢ^{k} can be found as follows.

That is, the unpunctured parity bits of the Sᵢ^{k} are as follow, when the parity bits for which j in the generated parity bit stream Pa(j) corresponds to a multiple of Pᵢ^{k}, for example, the unpunctured parity bits of Sᵢ¹ and Sᵢ² are taken into consideration.

Sᵢ¹: The parity bits for which j in the Pa(j) corresponds to a multiple of Pᵢ¹ are used as unpunctured parity bits.

Sᵢ²: The parity bits for which j in the Pa(j) corresponds to a multiple of Pᵢ² are used as unpunctured parity bits.

In this case, in order to satisfy the rate compatibility, the unpunctured parity bits of the Sᵢ² include the unpunctured parity bits of the Sᵢ¹. In order to satisfy this condition, the Pᵢ² should be an element of the Pᵢ¹. This process can be generalized as Equation (24):
Pᵢ^{k} is elemetns of Pᵢ^{j}, 1≦j≦k−1 (24)

When the condition of Equation (24) is satisfied, there is a restriction that the rate compatibility should be satisfied in the process of designing an RC-LDPC code from the ICZZ codes designed for respective code rates. However, there is no performance degradation.

Commonly, when the code rates supported by the RC-LDPC code do not have a broad range, there are many cases where the above condition is satisfied. However, because this condition cannot always be satisfied in the general design process, there is a need for a method for designing an RC-LDPC code with minimized performance degradation.

Therefore, the present invention proposes a design scheme for determining a possible short period and allowing unpunctured parity bits to have a constant interval within the determined period. That is, in the puncturing patterns of the punctured zigzag codes, all unpunctured parity bits are spaced apart at predetermined intervals. As such equivalent to determining the shortest possible period. The method for maintaining the form of the unpunctured parity bits being spaced apart at predetermined intervals while applying the rate compatibility restriction to the patterns, defines the possible short period and determines positions of unpunctured parity bits such that the interval should be constant within the period.

A puncturing period P that can support all puncturing patterns and has the shortest period for the puncturing patterns, can be expressed in Equation (25) as follows:
P=LCM(Pᵢ(1), Pᵢ(2), . . . , Pᵢ(Nᵢ)) (25)

In Equation (25), LCM denotes the least common multiple. The puncturing period P found by Equation (25) represents the shortest period that can express all puncturing patterns.

As described above, the bits are punctured in such a manner that the unpunctured parity bits should possibly be located at predetermined intervals within the determined period. Therefore, in the design process, positions of the unpunctured parity bits must be determined. In this case, the short period is determined in such a manner that the positions of the unpunctured parity bits should have a constant interval.

Meanwhile, a punctured zigzag code with a puncturing pattern Pᵢ(j) should have P/Pᵢ(j) unpunctured parity bits within the period P. The following is a method of determining positions of the unpunctured parity bits .
A. In a system where the low code rate greatly affects the system performance, for example, a system using an IR-based Type-II HARQ scheme, a method of determining positions of the unpunctured parity bits, determines the positions in such a manner that the unpunctured parity bits should possibly maintain a predetermined distance from the parity bits used only at the high code rate. This method determines the positions such that P/Pᵢ(1) unpunctured parity bits are spaced apart by a distance of Pᵢ(1) in the period P, and determines positions of the next P/Pᵢ(2)-P/Pᵢ(1) unpunctured parity bits among the empty positions. In this case, the positions of the P/Pᵢ(2)-P/Pᵢ(1) unpunctured parity bits are so determined as to possibly maintain the constant distance taking even the existing unpunctured parity bits into consideration. In addition, for a j^{th} code rate, positions are determined such that

$$\frac{P}{{P}_{i} ( j )} - {\sum }_{k = 1}^{j - 1} \frac{P}{{P}_{i} ( k )}$$

unpunctured parity bits are possibly located at predetermined intervals taking even the existing unpunctured parity bits into account.
B. When particular priority is given to every code rate, unpunctured parity bits of a code rate with the highest priority are located at predetermined interval in a specific period. Simply the unpunctured parity bits are possibly located at predetermined intervals according to priority.

Below is a description of a method for designing an exemplary RC-LDPC code that support code rates of ¾, ⅜and ⅙according to the present invention.

Table 3, Table 4 and Tale 5 show parameters of ICZZ codes that show the best performance at the code rates of ¾, ⅜and ⅙, respectively. The parameters of the high-performance ICZZ codes for the respective code rates are found by using the density evolution technique and satisfying the condition of Equation (18) presented in sub-process (1).

TABLE 3

| | |
|---|---|
| R(1) = 1 | d_{c}(1) = 14 |
| R(2) = 1 | d_{c}(2) = 14 |
| R(3) = 1 | d_{c}(3) = 14 |
| R(4) = 1 | d_{c}(4) = 14 |

TABLE 4

| | |
|---|---|
| R(1) = 1 | d_{c}(1) = 5 |
| R(2) = 1 | d_{c}(2) = 5 |
| R(3) = 1 | d_{c}(3) = 5 |
| R(4) = 1 | d_{c}(4) = 5 |
| R(5) = ⅓ | d_{c}(5) = 5 |
| R(6) = ⅓ | d_{c}(6) = 5 |
| R(7) = ⅓ | d_{c}(7) = 5 |

TABLE 5

| | |
|---|---|
| R(1) = 1 | d_{c}(1) = 3 |
| R(2) = 1 | d_{c}(2) = 3 |
| R(3) = 1 | d_{c}(3) = 3 |
| R(4) = 1 | d_{c}(4) = 3 |
| R(5) = ⅓ | d_{c}(5) = 3 |
| R(6) = ⅓ | d_{c}(6) = 3 |
| R(7) = ⅓ | d_{c}(7) = 3 |

Using the parameters shown in Table 3 through Table 5, sub-matrixes of a parity check matrix corresponding to each code rate can be generated as follows.
1. Code Rate ¾

S₁¹:(12, 0)-zigzag code, S₂¹:(12, 0)-zigzag code,

S₃¹:(12, 0)-zigzag code, S₄¹:(12, 0)-zigzag code
2. Code Rate ⅜

S₁²:(3, 0)-zigzag code, S₂²:(3, 0)-zigzag code,

S₃²:(3, 0)-zigzag code, S₄²:(3, 0)-zigzag code,

S₅²:(3, 0)-zigzag code, S₆²:(3, 0)-zigzag code,

S₇²:(3, 0)-zigzag code
3. Code Rate ⅙

S₁³:(1, 0)-zigzag code, S₂³:(1, 0)-zigzag code,

S₃³:(1, 0)-zigzag code, S₄³:(1, 0)-zigzag code,

S₅³:(1, 0)-zigzag code, S₆³:(1, 0)-zigzag code,

S₇³:(1, 0)-zigzag code

Next, in order to match the above zigzag codes in terms of the number of ‘1’s per row, the zigzag codes are converted into the following punctured zigzag codes in sub-process (2).
A) First Sub-Matrix

A first sub-matrix of the RC-LDPC code is found from S₁¹, S₁² and S₁³. From the foregoing equation of d_{c}(i)=gcd(d_{c}¹(i)−2, d_{c}²(i)−2 . . . , d_{c}^{N}_{ᵢ}(i)−2)+2, it is determined that d_{c}¹=gcd(12, 3, 1)+2=3. According to the puncturing pattern theorem, the S₁¹, S₁² and S₁³ can be replaced with S₁¹, S₁² and S₁³, respectively, without performance variation, as expressed in Equation (26) as follows:
S₁²:(12, 0)-Zigzag code→S₁¹:(1, 0)-Zigzag code with puncturing pattern (12)
S₁²:(3, 0)-Zigzag code→S₁²:(1, 0)-Zigzag code with puncturing pattern (3)
S₁³:(1, 0)-Zigzag code→4 S³:(1, 0)-Zigzag code with puncturing pattern (1) (26)

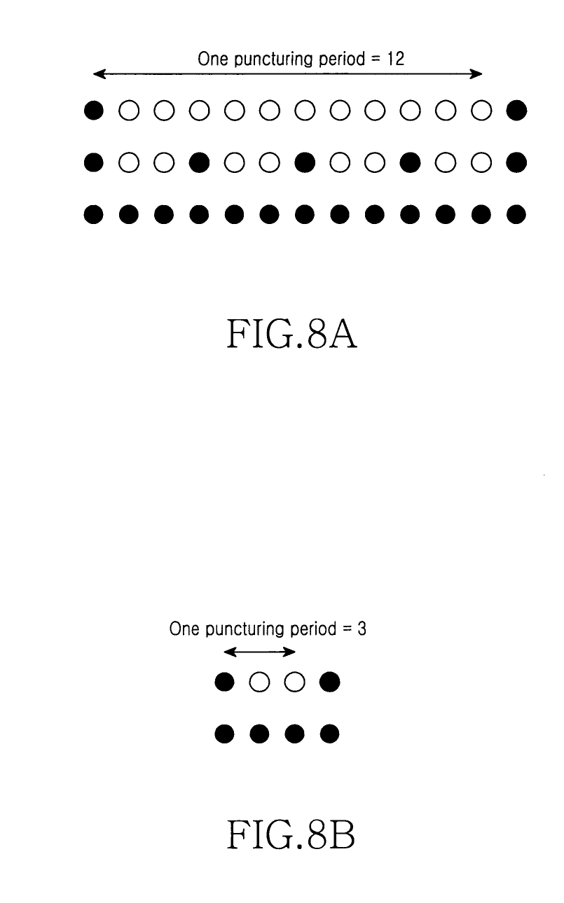

As shown in Equation (26), once the rate compatibility restriction is given to the puncturing patterns (12), (3) and (1), design for the first sub-matrix of a parity check matrix of an RC-LDPC code is completed. In this case, because P=LCM(1, 3, 12)=12 wherein 1 is an element of 3 and 12, and 3 is an element of 12, when the rate compatibility restriction is applied, there is no performance degradation. Although the method of generating the first sub-matrix has been described, it would be obvious to those skilled in the art that second, third and fourth sub-matrixes can also be generated in the same method. A puncturing pattern satisfying the rate compatibility restriction is illustrated in FIG. 8A wherein black circles represent unpunctured parity bits and white circles represent punctured parity bits.
B) Fifth Sub-Matrix

A fifth sub-matrix of the RC-LDPC code is found from S₅² and S₅³. From the foregoing equation d_{c}(i)=gcd(d_{c}¹(i)−2, d_{c}²(i)−2, . . . , d_{c}^{N}_{ᵢ}(i)−2)+2, it is determined that d_{c}¹=gcd(3, 1)+2=3. According to the puncturing pattern theorem, the S₅² and S₅³ are replaced with S₅^{2′} and S₅^{3′}, respectively, without performance variation, as expressed in Equation (27) as follows:
S₅²:(3, 0)-Zigzag code→S₅^{2′}:(1, 0)-Zigzag code with puncturing pattern (3)
S₅³:(1, 0)-Zigzag code→S₅^{3′}:(1, 0) - Zigzag code with puncturing pattern (1) (27)

As shown in Equation (27), once the rate compatibility restriction is given to the puncturing patterns (3) and (1), design for the fifth sub-matrix of a parity check matrix of an RC-LDPC code is completed. In this case, because P=LCM(1, 3)=3 wherein 1 is an element of 3, when the rate compatibility restriction is applied, there is no performance degradation. Although the method of generating the fifth sub-matrix has been described, it would be obvious to those skilled in the art that sixth and seventh sub-matrixes can also be generated in the same method. A puncturing pattern satisfying the rate compatibility restriction is illustrated in FIG. 8B wherein black circles represent unpunctured parity bits and white circles represent punctured parity bits.

The puncturing patterns of the RC-LDPC code, found in the above method, are illustrated in Table 6 below.

TABLE 6

| | Puncturing patterns | | |
|---|---|---|---|
| Sub-matrix | ¾ | ⅜ | ⅙ |
| 1 | 100000000000 | 100100100100 | 111111111111 |
| 2 | 100000000000 | 100100100100 | 111111111111 |
| 3 | 100000000000 | 100100100100 | 111111111111 |
| 4 | 100000000000 | 100100100100 | 111111111111 |
| 5 | 000 | 100 | 111 |
| 6 | 000 | 100 | 111 |
| 7 | 000 | 100 | 111 |

Table 6 shows puncturing patterns for one period, wherein ‘1’ denotes an unpunctured parity bit and ‘0’ denotes a punctured parity bit.

Referring to Table 6, for the code rate ¾, because the puncturing patterns for 5^{th}, 6^{th} and 7^{th} zigzag encoders of the sub-matrixes are all zero, the 5^{th}, 6^{th} and 7^{th} zigzag encoders are not used. The zigzag encoders are not used, and this is called “pruning”, because the puncturing patterns are all zero.

As described above, a code rate of the RC-LDPC code proposed in the present invention is adjusted by puncturing and pruning. Therefore, compared with the general rate-compatible codes whose code rate is adjusted depending on only the puncturing, the proposed RC-LDPC code can support various code rates. In other words, when the code rate is adjusted depending on only the puncturing, a ratio of puncturing nodes excessively increases, thereby causing an increase in performance deterioration and making the error floor become serious.

The RC-LDPC code can be designed using the R(i) values of Table 3 through Table 5 and the puncturing patterns of Table 6. A description will now be made of structures of an encoder and a decoder for the designed RC-LDPC code according to an embodiment of the present invention.

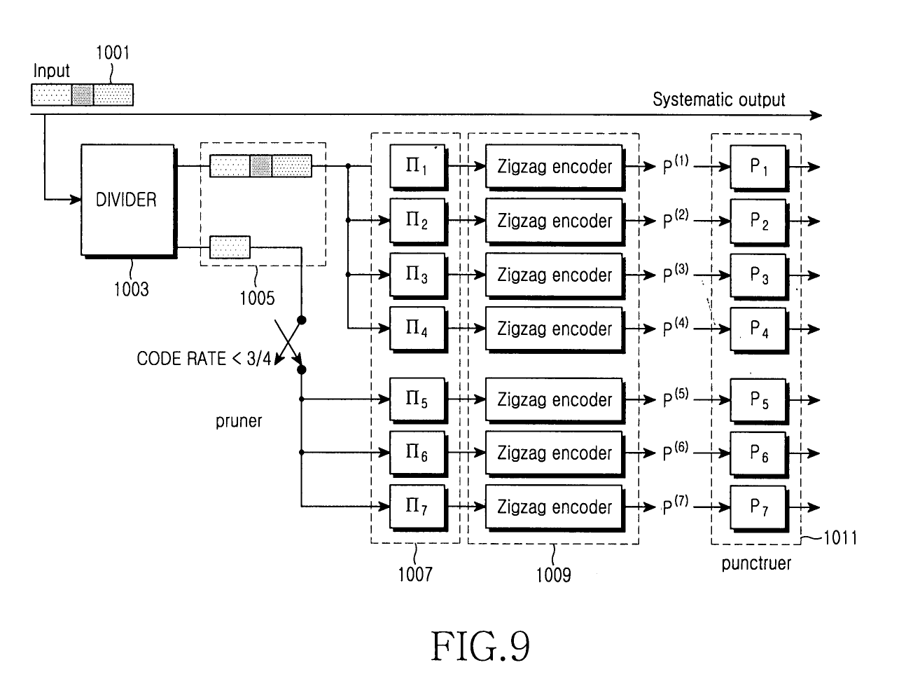

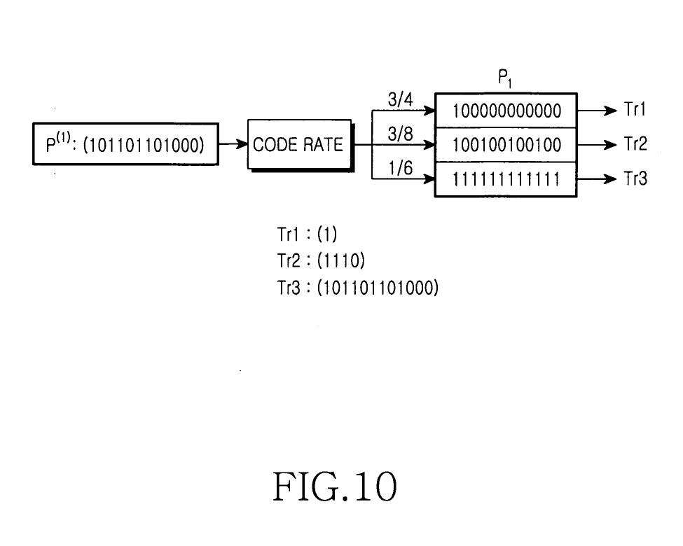

FIG. 9 is a diagram schematically illustrating a structure of an RC-LDPC encoder according to an embodiment of the present invention, and FIG. 10 is a diagram for a description of an operation and structure of the puncturer of FIG. 9 according to the present invention.

Referring to FIG. 9, there is shown an exemplary structure of an RC-LDPC encoder according to an embodiment of the present invention. In particular, FIG. 9 illustrates an RC-LDPC encoder including a puncturer for puncturing output values of zigzag encoders for a rate code ¾, like FIG. 6. As illustrated in FIG. 9, the RC-LDPC encoder includes an information bit block 1001, a divider 1003, a sub block 1005, a pruner, an interleaver 1007, a zigzag encoder 1009, and a puncturer 1011. The puncturer elements 1011 are separately designed in association with their corresponding zigzag encoder elements 1009. Simply the puncturers P₁, P₂, P₃, P₄, P₅, P₆ and P₇ are designed in association with their corresponding zigzag encoder elements 1009 on a one-to-one basis.

It is assumed in FIG. 10 that the parity bits generated in the first zigzag encoder are P⁽¹⁾(101101101000).

In FIG. 10, Tr1 denotes unpunctured parity bits for a code rate ¾, Tr2 denotes unpunctured parity bits for a code rate ⅜, and Tr3 denotes unpunctured parity bits for a code rate ⅙.

A relationship between Tr1, Tr2 and Tr3 will now be described. It can be noted that the parity bits transmitted at a low code rate include the parity bits transmitted at a high code rate. Simply the Tr1 transmits (1) at the code rate ¾, and the Tr2 is allowed to transmit only (110) except for the transmitted bit ‘1’ among (1110) at the code rate ⅜ because the first bit ‘1’ was previously transmitted at Tr1. In the same manner, at the code rate ⅙, the Tr3 is allowed to transmit only (01010100) except for the bits previously transmitted at the Tr1 and Tr2, among (101101101000).

Due to the foregoing characteristics, the RC-LDPC code can be applied to the IR-based Type-II HARQ scheme. Similarly, the puncturers P₂ through P₇ can be constructed in the same method.

The structure of the RC-LDPC encoder has been described so far. A brief description will now be made of an RC-LDPC decoder. The RC-LDPC code can be decoded by one of the foregoing three types of decoding methods, i.e., a parallel decoder-based decoding method, a serial decoder-based decoding method and a hybrid decoder-based decoding method. However, the present invention is different from the prior art in that decoding is achieved by replacing an initial value of a variable node corresponding to a punctured parity node with a 0 (Null) value in the process of initializing the decoding process.

As can be understood from the foregoing description, an apparatus and method for generating an LDPC code based on a zigzag code in a communication system can support various code rates using symbol puncturing and pruning. The proposed RC-LDPC code has almost no performance degradation due to the support of the rate compatibility because it shows almost same performance as that of the ICZZ code designed to be suitable for a particular code rate.

In addition, compared with the conventional rate-compatible codes whose code rate is adjusted depending on only the puncturing, the proposed RC-LDPC code can support various code rates because its code rate is adjusted depending on the puncturing and pruning.

While the invention has been shown and described with reference to a certain preferred embodiment thereof, it will be understood by those skilled in the art that various changes in form and details may be made therein without departing from the spirit and scope of the invention as defined by the appended claims.

What is claimed is:

1. A method for generating a low density parity check (LDPC) code supporting various code rates, the method comprising the steps of:
finding a plurality of parity check matrixes showing the best performance at a predetermined code rate;
matching the parity check matrixes in terms of the number of ‘1’s per row in units of sub-matrixes of each of the matrixes; and
converting the plurality of parity check matrixes into one matrix, and combining punctured zigzag codes generated for every code rate into one punctured zigzag code.

2. The method of claim 1, wherein a parameter of the plurality of parity check matrixes satisfies the following condition,
R^{k}(i)≧R^{j}(i),k>j
where R^{k}(i) denotes a ratio of non-zero columns in a parity check matrix, R^{j}(i) denotes an i^{th} sub-matrix matched to a code rate specified in a system setup process, and k, j and i denote random variables.

3. The method of claim 1, wherein the matching step comprises:
converting the plurality of parity check matrixes into one parity check matrix;
wherein a zigzag code used as the sub-matrix is replaced with a punctured zigzag code, and a predetermined sub-matrix of a parity check matrix is found from predetermined sub-matrixes in which the number of information bits input to a zigzag encoder is not 0 among the plurality of parity check matrixes.

4. The method of claim 3, wherein the matching step comprises:
determining a predetermined sub-matrix H of the converted one parity check matrix according to predetermined sub-matrixes of the plurality of parity check matrixes;
wherein the sub-matrix H is defined by a parameter representing a ratio of information bits input to a zigzag encoder and a parameter of a code used by the zigzag encoder, and the sub-matrix H represents a zigzag code.

5. The method of claim 4, wherein the step of determining a predetermined sub-matrix H comprises:
ordering the parity check matrixes; and
converting zigzag codes mapped to the parity check matrixes into a zigzag code punctured according to the parity check matrixes.

6. The method of claim 1, wherein the number of ‘1’s per row given in units of sub-matrixes is calculated by
d_{c}(i)=gcd(d_{c}¹(i)−2, d_{c}²(i)−2, . . . , d_{c}^{N}_{ᵢ}(i)−2)+2
where d_{c}(i) denotes the number of ‘1’s per row of an id sub-matrix in a parity check matrix of a rate-compatible LDPC code, gcd( ) denotes the greatest common divisor, and i denotes a random variable.

7. The method of claim 1, wherein the combining step comprises applying rate compatibility to each of puncturing patterns.

8. The method of claim 7, wherein to satisfy the rate compatibility, unpunctured parity bits of a first sub-matrix include unpunctured parity bits of a second sub-matrix, and parity bits of the first sub-matrix are elements of parity bits of the second sub-matrix.

9. A method for generating a low density parity check (LDPC) code supporting various code rates, the method comprising the steps of:
determining the shortest period of a puncturing pattern; and
determining positions of unpunctured parity bits such that the unpunctured parity bits have a constant interval within the determined period.

10. The method of claim 9, wherein a puncturing period P having the shortest period is calculated by
P=LCM(Pᵢ(1), Pᵢ(2), . . . , Pᵢ(Nᵢ))
where LCM denotes the least common multiple, and the puncturing period P represents the shortest period that can express all puncturing patterns.

11. The method of claim 9, wherein the step of determining positions of unpunctured parity bits comprises:
determining the positions such that a predetermined distance from parity bits used at a high code rate is maintained; and
determining the positions of the unpunctured parity bits such that a predetermined distance is maintained taking into account existing unpunctured parity bits among empty positions.

12. The method of claim 9, wherein the step of determining positions of unpunctured parity bits comprises determining the positions such that the unpunctured parity bits maintain a predetermined interval according to priority.

13. The method of claim 9, wherein parity bits transmitted at a low code rate include parity bits transmitted at a high code rate.

14. The method of claim 9, wherein the LDPC code is decoded by inserting a null value as an initial value of a variable node mapped to a punctured parity node in an initialization process.

15. An apparatus for generating a low density parity check (LDPC) code supporting various code rates, the apparatus comprising:
a zigzag encoder;
a divider for dividing input information bits;
a pruner for receiving the information bits divided by the divider, and pruning an input to the zigzag encoder, a puncturing pattern of the input being a zero (null) for the input information bits; and
a puncturer for performing puncturing to match zigzag codes output from the zigzag encoder in terms of the number of ‘1’s per row.

16. The apparatus of claim 15, wherein the puncturing pattern is generated by determining the shortest period as a puncturing period, and determining positions of unpunctured parity bits such that the unpunctured parity bits have a constant interval within the determined period.

17. The apparatus of claim 16, wherein a puncturing period P having the shortest period is calculated by
P=LCM(Pᵢ(1), Pᵢ(2), . . . , Pᵢ(Nᵢ))
where LCM denotes the least common multiple, and the puncturing period P represents the shortest period that can express all puncturing patterns.

18. The apparatus of claim 16, wherein the positions of the unpunctured parity bits are determined such that a predetermined distance from parity bits used at a high code rate is maintained, and a predetermined distance is maintained taking into account existing unpunctured parity bits among empty positions.

19. The apparatus of claim 16, wherein the positions of the unpunctured parity bits are determined such that the unpunctured parity bits maintain a predetermined interval according to priority.

20. The apparatus of claim 16, wherein parity bits transmitted at a low code rate include parity bits transmitted at a high code rate.

21. The apparatus of claim 15, wherein a plurality of parity check matrixes are converted into one parity check matrix, zigzag codes used as sub-matrixes are replaced with punctured zigzag codes, and the zigzag codes are matched in terms of the number of ‘1’s.

22. The apparatus of claim 21, wherein the zigzag codes corresponding to the parity check matrixes are converted into punctured zigzag codes according to the parity check matrixes.

23. The apparatus of claim 15, wherein the number of ‘1’s per row given in units of sub-matrixes is calculated by
d_{c}(i)=gcd(d_{c}¹(i)−2, d_{c}²(i)−2, . . . , d_{c}^{N}_{ᵢ}(i)−2)+2
where d_{c}(i) denotes the number of ‘1’s per row of an i^{th} sub-matrix in a parity check matrix of a rate-compatible LDPC code, gcd( ) denotes the greatest common divisor, and i denotes a random variable.

24. The apparatus of claim 15, wherein rate compatibility is applied to each of puncturing patterns and punctured zigzag codes are combined.

25. The apparatus of claim 24, wherein in order to satisfy the rate compatibility, unpunctured parity bits of a first sub-matrix include unpunctured parity bits of a second sub-matrix, and parity bits of the first sub-matrix are elements of parity bits of the second sub-matrix.
